(19) United States
(12) Patent Application Publication
(10) Pub. No.: US 2023/0207658 A1
(43) Pub. Date: Jun. 29, 2023

(54) SEMICONDUCTOR STRUCTURE AND METHOD FOR FORMING SAME

(71) Applicant: CHANGXIN MEMORY TECHNOLOGIES, INC., Hefei City, Anhui (CN)

(72) Inventor: Yutong SHEN, Hefei City (CN)

(73) Assignee: CHANGXIN MEMORY TECHNOLOGIES, INC., Hefei City, Anhui (CN)

(21) Appl. No.: 17/663,183

(22) Filed: May 12, 2022

(30) Foreign Application Priority Data
Dec. 24, 2021 (CN) 202111602363.9

(51) Int. Cl. H01L 29/51; H01L 21/02; H01L 21/28

(52) U.S. Cl. CPC H01L 29/513; H01L 29/517; H01L 21/02181; H01L 21/02189; H01L 21/02192; H01L 21/02194; H01L 21/02148; H01L 21/0214; H01L 21/02164; H01L 21/0217; H01L 21/28158

(57) ABSTRACT

A semiconductor structure includes a substrate and a gate stack structure located on the substrate. The gate stack structure includes: a high-K dielectric layer, a first barrier layer in contact with the high-K dielectric layer, a work function layer located on a side of the high-K dielectric layer away from the substrate, and a gate electrode layer located on a side of the work function layer away from the substrate. The first barrier layer contains the same metal element as the high-K dielectric layer.

### CROSS-REFERENCE TO RELATED APPLICATION

The present application claims priority to Chinese Application No. 202111602363.9 filed on Dec. 24, 2021, the disclosure of which is hereby incorporated by reference in its entirety.

### BACKGROUND

In the field of dynamic random access memory (DRAM) manufacturing, with the decreasing size, the thinning of silicon dioxide (SiO₂) as a dielectric layer has brought the gate leakage that cannot be ignored, so a high-K dielectric layer is introduced in the preparation of the dielectric layer of the device.

### SUMMARY

The disclosure relates to, but is not limited to, the technical field of semiconductors, and in particular to a semiconductor structure and a method for forming the same.

In a first aspect, the embodiments of the present disclosure provide a semiconductor structure, which includes a substrate and a gate stack structure located on the substrate. The gate stack structure includes: a high-K dielectric layer, a first barrier layer in contact with the high-K dielectric layer, a work function layer located on a side of the high-K dielectric layer away from the substrate, a gate electrode layer located on a side of the work function layer away from the substrate. The first barrier layer contains the same metal element as that of the high-K dielectric layer.

In a second aspect, the embodiments of the disclosure provide a method for forming a semiconductor structure, which includes: providing a substrate; forming a high-K dielectric layer and a first barrier layer in contact with the high-K dielectric layer on the substrate; forming a work function layer on a side of the high-K dielectric layer away from the substrate; forming a gate electrode layer on the work function layer to form a gate stack structure on the substrate. The first barrier layer contains the same metal element as that of the high-K dielectric layer.

### BRIEF DESCRIPTION OF THE DRAWINGS

In the drawings (which are not necessarily drawn to scale), similar reference numerals can describe similar parts in different views. Similar reference numerals with different letter suffixes can indicate different examples of similar parts. The drawings generally show the various embodiments discussed herein by way of example and not limitation.

FIG. 1A is a structural diagram of HKMG structure;

FIG. 1B is a structural diagram of a semiconductor structure formed based on HKMG structure;

FIG. 1C is a schematic diagram of oxygen transmission directions among HKMG dielectric layers;

FIG. 1D is a schematic diagram of the reaction occurring when oxygen enters HKMG;

FIG. 2A is a first schematic flow diagram of methods for forming semiconductor structures provided by the embodiments of the disclosure;

FIG. 2B is a second schematic flow diagram of methods for forming semiconductor structures provided by the embodiments of the disclosure;

FIG. 2C is a first schematic structural diagram of semiconductor structures provided by the embodiments of the disclosure;

FIG. 2D is a second schematic structural diagram of semiconductor structures provided by the embodiments of the disclosure;

FIG. 2E is a third schematic structural diagram of semiconductor structures provided by the embodiments of the disclosure;

FIG. 3A is a schematic flow diagram of a method for forming a semiconductor structure provided by an embodiment of the disclosure;

FIG. 3B is a first schematic structural diagram of semiconductor structures provided by the embodiments of the disclosure;

FIG. 3C is a second schematic structural diagram of semiconductor structures provided by the embodiments of the disclosure;

FIG. 4A is a schematic flow diagram of a method for forming a semiconductor structure provided by an embodiment of the disclosure;

FIG. 4B is a first schematic structural diagram of semiconductor structures provided by the embodiments of the disclosure;

FIG. 4C is a second schematic structural diagram of semiconductor structures provided by the embodiments of the disclosure;

FIG. 4D is a third schematic structural diagram of semiconductor structures provided by the embodiments of the disclosure;

FIG. 5A is a schematic flow diagram of a method for forming a semiconductor structure provided by an embodiment of the disclosure; and

FIG. 5B is a schematic structural diagram of a semiconductor structure provided by an embodiment of the disclosure.

### DETAILED DESCRIPTION

Exemplary implementation modes disclosed in the disclosure will be described in more detail below with reference to the accompanying drawings. Although exemplary implementation modes of the disclosure are shown in the drawings, it should be understood that the disclosure can be implemented in various forms and should not be limited by the specific implementation modes set forth herein. On the contrary, these implementation modes are provided to enable a more thorough understanding of the disclosure and to fully convey the scope disclosed by the disclosure to those skilled in the art.

In the following description, numerous specific details are given in order to provide a more thorough understanding of the disclosure. However, it will be obvious to one skilled in the art that the present disclosure can be practiced without one or more of these details. In other examples, in order to avoid confusion with the disclosure, some technical features known in the field are not described; that is, not all the features of the actual embodiments are described here, and well-known functions and structures are not described in detail.

In the drawings, the dimensions of layers, regions and elements and their relative dimensions may be exaggerated for clarity. The same reference numerals refer to same elements throughout.

It should be understood that when an element or layer is referred to as being “on”, “adjacent to”, “connected to” or “coupled to” other elements or layers, it may be directly on, adjacent to, connected to or coupled to other elements or layers, or there may be intervening elements or layers. On the contrary, when an element is referred to as being “directly on”, “directly adjacent to”, “directly connected to” or “directly coupled to” other elements or layers, there is no intervening element or layer. It should be understood that although the terms first, second and third can be used to describe various elements, components, regions, layers and/or parts, these elements, components, regions, layers and/or parts should not be limited by these terms. These terms are only used to distinguish one element, component, region, layer or part from another element, component, region, layer or part. Therefore, the first element, component, region, layer or part discussed below can be expressed as the second element, component, region, layer or part without departing from the teaching of the disclosure. When the second element, component, region, layer or part is discussed, it does not mean that the first element, component, region, layer or part necessarily exists in the disclosure.

The terminology used here is only for the purpose of describing specific embodiments and is not a limitation of the disclosure. As used herein, singular forms of “a”, “an” and “said/the” are also intended to include plural forms, unless the context clearly indicates otherwise. It should also be understood that the terms “include” and/or “consist of”, when used in this specification, determine the presence of said features, integers, steps, operations, elements and/or components, but do not exclude the presence or addition of one or more other features, integers, steps, operations, elements, components and/or groups. As used herein, the term “and/or” includes any and all combinations of related listed items.

There are a lot of oxygen vacancies in a high-K dielectric layer of dielectric layers of high-K metal gate (HKMG), which will affect electrical parameters and/or performance of HK devices. Moreover, due to the existence of oxygen vacancies, the growth of the silicon dioxide layer on a surface will be further enhanced.

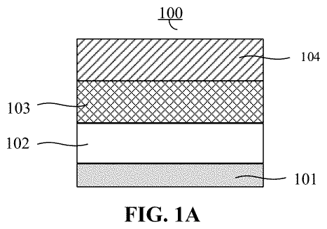

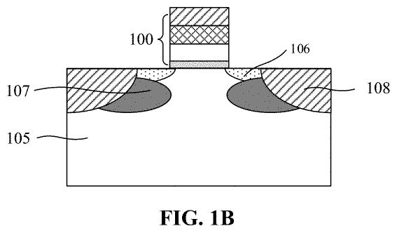

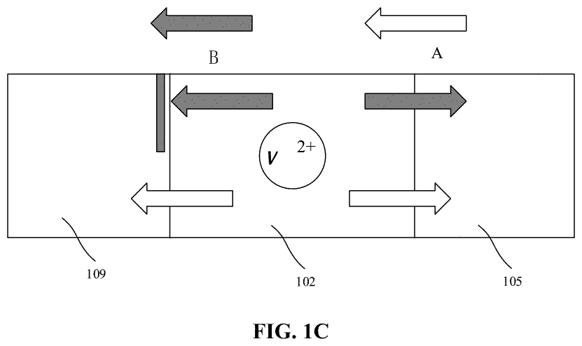

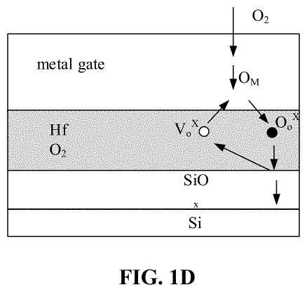

In order to better understand semiconductor structures provided by the embodiments of the disclosure, a HKMG structure and a semiconductor structure formed based on the HKMG structure will be explained. As shown in FIGS. 1A and 1B, the semiconductor structure includes a high-K metal gate structure 100, a substrate 105, a Lightly Doped Drain (LDD) structure 106, halo rings 107, and source and drain regions 108.

The high-K metal gate structure 100 includes an insulating layer 101, a high-K dielectric layer 102, a work function layer 103 and a gate electrode layer 104. The insulating layer 101 includes a SiO₂ layer, the high-K dielectric layer 102 includes a hafnium dioxide (HfO₂) layer, the work function layer 103 includes a lanthanum oxide (La₂O₃) layer, and the gate electrode layer 104 includes a titanium nitride (TiN) layer.

From FIG. 1A and FIG. 1B, it can be seen that the substrate 105 is in contact with the insulating layer 101, and the insulating layer 101 is in contact with the high-K dielectric layer 102, so the reaction process described in formula (1) may occur in the high-K dielectric layer of HKMG.

HfO₂+½Si→V_{O}²⁺+2e⁻+½SiO₂ (1);

As shown in FIG. 1C, the substrate 105 can be a silicon substrate, and is in contact with the high-K dielectric layer 102. The metal gate 109 (including the work function layer and the gate electrode layer) is in contact with the high-K dielectric layer 102. In FIG. 1C, A represents a transmission direction of oxygen, and B represents a transmission direction of electrons.

The reaction of formula (1) occurs in the high-K dielectric layer 102, resulting in the transmission of electrons and O. In FIG. 1C, O in the high-K dielectric layer 102 can be transferred to the substrate 105, leaving many oxygen vacancies V_{O}²⁺ in the high-K dielectric layer 102. Most of the electrons are transferred to the metal gate 109, and only a few electrons are transferred to the substrate 105, which can reduce a carrier concentration at the channel surface and also the effective work function, thus lowering the electrical characteristics of the circuit.

In addition, referring to FIG. 1D, oxygen in the subsequent process or oxygen in the air may enter the metal gate and react to generate O_{M} as shown in formula (2). V_{O}^{X} (oxygen vacancies) in the high-K dielectric layer may react with the oxygen O_{M} entering the metal gate, as shown in formula (3), to generate interstitial oxygen O_{O}^{X}, which may continue to react as shown in formula (4) to generate oxygen vacancies and silicon oxide SiO_{X}, thereby forming a SiO₂ layer on the surface of the silicon substrate.

½O₂(g)=O_{M} (2);

V_{O}^{X}+O_{M}=O_{O}^{X} (3);

O_{O}^{X}=V_{O}^{X}+SiO_{X} (4).

O_{M} represents oxygen entering the metal gate, O_{O}^{X} represents interstitial oxygen, and V_{O}^{X} represents oxygen vacancies.

The existence of a large number of oxygen vacancies in the high-K dielectric layer is unfavorable to the threshold voltage of HK devices and the stability of the devices. Too many oxygen vacancies can lead to Fermi pinning at the interface, which can increase the threshold voltage and reduce the switching speed of devices. Moreover, the oxygen vacancies may become a medium of O transmission, which further enhances the growth of the SiO₂ layer on the surface, thereby affecting the thickness of the SiO₂ layer at the interface and thus the equivalent oxide thickness (EOT) of the device. Thus, the threshold voltage and power consumption of the device are increased, making the overall device performance uncontrollable. These become problems to be solved in HKMG devices.

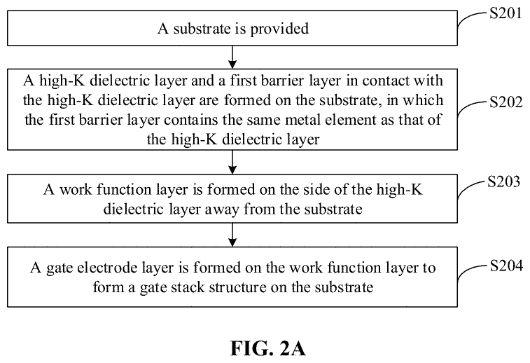

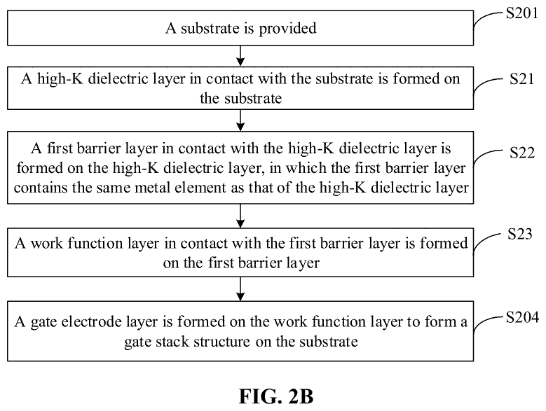

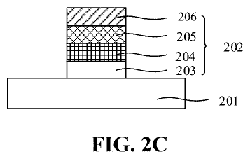

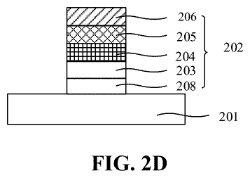

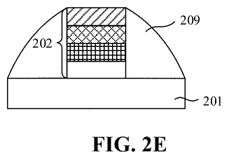

On the basis of understanding the HK oxygen transmission path, the embodiments of the disclosure provide a method for forming a semiconductor structure. Referring to FIG. 2A, the method includes S201 to S204.

At S201, a substrate is provided.

At S202, a high-K dielectric layer and a first barrier layer in contact with the high-K dielectric layer are formed on the substrate, in which the first barrier layer contains the same metal element as the metal element of the high-K dielectric layer.

Here, S202 may include the following three cases.

In Case 1, a high-K dielectric layer is formed on the substrate, and a first barrier layer is formed on the high-K dielectric layer. Therefore, the first barrier layer finally formed is in contact with the upper surface of the high-K dielectric layer.

In Case 2, a first barrier layer is formed on the substrate, and a high-K dielectric layer is formed on the first barrier layer. Therefore, the first barrier layer finally formed is in contact with the lower surface of the high-K dielectric layer.

In Case 3, a first barrier layer is formed on the substrate, a high-K dielectric layer is formed on the first barrier layer, and a first barrier layer is formed on the high-K dielectric layer. Therefore, the first barrier layers finally formed are in contact with both the upper surface and the lower surface of the high-K dielectric layer.

At S203, a work function layer is formed on the side of the high-K dielectric layer away from the substrate.

At S204, a gate electrode layer is formed on the work function layer, to form a gate stack structure on the substrate.

Here, the gate stack structure may be a HKMG structure.

In the method for forming the semiconductor structure provided by the embodiments of the disclosure, a substrate is provided. A high-K dielectric layer and a first barrier layer in contact with the high-K dielectric layer are formed on the substrate. A work function layer is formed on that side of the high-K dielectric layer away from the substrate. A gate electrode layer is formed on the work function layer to form a gate stack structure on the substrate. The first barrier layer contains the same metal element as that of the high-K dielectric layer. Thus, firstly, the barrier layer is used to block the transmission of O. On the one hand, the formation of oxygen vacancies in the high-K dielectric layer can be reduced, reducing the drift of threshold voltage and thus improving the stability of the device. On the other hand, the growth of the insulating layer can also be reduced. Secondly, the first barrier layer also plays a certain role in regulating the metal work function, so that the threshold voltage of the device can be reduced, and the power consumption of the device can be reduced. Consequently, the device performance can be further optimized. In addition, only the barrier layer is added in the semiconductor structure of the disclosure, so the structure is relatively simple, which can adapt to the related process design. Moreover, the first barrier layer contains the same metal element as that of the high-K dielectric layer, which can effectively reduce the manufacturing process flow and improve the efficiency.

In the embodiments of the disclosure, the substrate may be a silicon substrate, and may also include other semiconductor elements such as germanium (Ge), or semiconductor compounds such as silicon carbide (SiC), gallium arsenide (GaAs), gallium phosphide (GaP), indium phosphide (InP), indium arsenide (InAs) or indium antimonide (InSb), or other semiconductor alloys such as silicon germanium (SiGe), gallium arsenide phosphide (GaAsP), indium aluminum arsenide (AlInAs), aluminum gallium arsenide (AlGaAs), indium gallium arsenide (GaInAs), indium gallium phosphide (GaInP), and/or indium gallium arsenide phosphide (GaInAsP) or their combinations.

In some embodiments, the substrate may include a doped epitaxial layer, a gradient semiconductor layer, and/or a semiconductor layer on another different type of semiconductor layer (such as a silicon layer on a silicon germanium layer). The substrate may include various doped regions doped with a P-type dopant such as boron or boron difluoride (BF₂), an N-type dopant such as phosphorus or arsenic, or combinations thereof. The doped regions may be formed on the semiconductor substrate, in a P-well structure, in an N-well structure, in a double-well structure, or the doped regions may be formed by using a bump structure.

Because the dielectric constant of HfO₂ is about 25, the forbidden band width is 5.9 eV, and the conduction band offset between HfO₂ and silicon is 1.5 eV, the carriers are not enough to cross the barrier height of 1.5 eV to form gate leakage current. HfO₂ is usually chosen as the high-K dielectric layer because of its advantages of wide band gap, high dielectric constant and high stability at Si interface. In the embodiments of the disclosure, the high-K dielectric layer may include hafnium-based material layers, such as at least one of HfO₂ layer, HfSiO layer, HfSiON layer, HMO layer, HfSiO layer and HfZrO layer.

The deposition method of the high-K dielectric layer may include chemical vapor deposition (CVD), such as low temperature chemical vapor deposition (LTCVD), low pressure chemical vapor deposition (LPCVD), rapid thermal chemical vapor deposition (RTCVD) and plasma enhanced chemical vapor deposition (PECVD).

The method of forming the work function layer may include at least one of ALD, PEALD, CVD, PECVD, PVD, and/or their combinations. A single work function layer or multiple work function layers may be formed by deposition.

The method of forming the gate electrode layer may include at least one of physical vapor deposition (PVD), CVD, atomic layer deposition (ALD), PECVD, remote plasma chemical vapor deposition (RPCVD), metal-organic chemical vapor deposition (MOCVD), sputtering, plating and other suitable methods.

The first barrier layer may include a lanthanum hafnium oxide layer, for example, a LaHfOₓ material layer.

The material used for the work function layer may be an N-type and/or P-type work function material based on the device type corresponding to the gate stack structure. The P-type work function material includes TiN, Tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other suitable P-type work function materials, and/or combinations thereof. An exemplary N-type work function material includes La₂O₃, titanium (Ti), silver (Ag), tantalum aluminide (TaAl), tantalum aluminum carbide (TaAlC), tantalum aluminum nitride (TiAlN), tantalum carbide (TaC), carbon tantalum nitride (TaCN), tantalum silicon nitride (TaSiN), manganese (Mn), zirconium (Zr), other suitable N-type work function materials, and/or combinations thereof. The N-type work function material may be configured to have a desired work function value of the gate electrode of an N-channel field effect transistor (NFET). The P-type work function material may be configured to have a desired work function value of the gate electrode of a P-channel field effect transistor (PFET).

The gate electrode layer may include copper, tungsten, metal alloy, metal silicide, other conductive materials or their combinations.

In some embodiments, the high-K dielectric layer may include at least one of silicon hafnium oxide layer, silicon hafnium oxynitride layer, tantalum hafnium oxide layer, titanium hafnium oxide layer and zirconium hafnium oxide layer.

In some embodiments, for Case 1 mentioned above, referring to FIG. 2B, S202 may include S21 and S22.

At S21, a high-K dielectric layer in contact with the substrate is formed on the substrate.

At S22, a first barrier layer in contact with the high-K dielectric layer is formed on the high-K dielectric layer, in which the first barrier layer contains the same metal element as that of the high-K dielectric layer.

S203 may include S23 of forming on the first barrier layer a work function layer in contact with the first barrier layer.

The S201 to S204 are further explained below with reference to FIG. 2C. FIG. 2C is illustrated taking the formation of a high-K dielectric layer on the substrate and a first barrier layer on the high-K dielectric layer, that is, the above-mentioned Case 1 as an example. Referring to FIG. 2C, a high-K dielectric layer 203 contacting with the substrate 201 is formed on the substrate 201. A first barrier layer 204 contacting with the high-K dielectric layer 203 is formed on the high-K dielectric layer 203. A work function layer 205 contacting with the first barrier layer 204 is formed on the first barrier layer 204. A gate electrode layer 206 contacting with the work function layer 205 is formed on the work function layer 205.

Based on the method for forming a semiconductor structure provided in the S201 to S204, the embodiments of the disclosure provide a semiconductor structure, which includes a substrate and a gate stack structure located on the substrate. The gate stack structure includes a high-K dielectric layer, a first barrier layer in contact with the high-K dielectric layer, a work function layer located on the side of the high-K dielectric layer away from the substrate, a gate electrode layer located on the side of the work function layer away from the substrate. The first barrier layer contains the same metal element as that of the high-K dielectric layer.

The work function layer located on the side of the high-K dielectric layer away from the substrate includes the following two situations: 1) the high-K dielectric layer is in contact with the work function layer; 2) the high-K dielectric layer is not in contact with the work function layer. For example, when the first barrier layer is in contact with the lower surface of the high-K dielectric layer, the work function layer is in contact with the high-K dielectric layer and is located on the high-K dielectric layer. When the first barrier layer is in contact with the upper surface of the high-K dielectric layer, the work function layer is not in contact with the high-K dielectric layer, and the work function layer is located on the upper surface of the first barrier layer and in contact with the first barrier layer. When the first barrier layer is in contact with both the upper surface and the lower surface of the high-K dielectric layer, the work function layer is in contact with the first barrier layer on the upper surface of the high-K dielectric layer, instead of the first barrier layer under the lower surface of the high-K dielectric layer.

The semiconductor structure provided by the embodiments of the disclosure may be included in the process of forming the integrated circuit or part thereof, and may include static random-access memory (SRAM) and/or other logic circuits, passive components such as resistors, capacitors and inductors, and active components such as PFETs, NFETs, metal oxide semiconductor field effect transistors (MOSFET), complementary metal oxide semiconductor (CMOS) transistors, bipolar transistors, high voltage transistors, high frequency transistors, other memory cells, their combination and/or other semiconductor devices.

In some embodiments, the first barrier layer is located on the side of the high-K dielectric layer away from the substrate. The embodiments of the disclosure correspond to Case 1 mentioned above.

The semiconductor structure provided in the embodiments will be further described in detail below with reference to FIG. 2C, which is a schematic diagram of the semiconductor structure provided for Case 1 mentioned above. Referring to FIG. 2C, the semiconductor structure includes a substrate 201 and a gate stack structure 202 on the substrate 201. The gate stack structure 202 includes a high-K dielectric layer 203, a first barrier layer 204 in contact with the high-K dielectric layer 203, a work function layer 205 on the high-K dielectric layer 203, and a gate electrode layer 206 on the work function layer 205. In the embodiments of the disclosure, the substrate 201 is a silicon substrate, the high-K dielectric layer 203 is an HfO₂ layer, the first barrier layer 204 is a LaHfOₓ layer, the work function layer 205 is a La₂O₃ layer, and the gate electrode layer 206 is a TiN layer. The first barrier layer 204 contains the same Hf element as that of the high-K dielectric layer 203.

In some embodiments, the high-K dielectric layer may include at least one of silicon hafnium oxide layer, silicon hafnium oxynitride layer, tantalum hafnium oxide layer, titanium hafnium oxide layer and zirconium hafnium oxide layer.

In some embodiments, the method further includes S205 of forming an insulating layer on the substrate, in which the insulating layer includes at least one of a silicon oxide layer, a silicon nitride layer and a silicon oxynitride layer. Here, S205 may be performed after S201.

Based on the method for forming a semiconductor structure provided in S201 to S205, the gate stack structure in some embodiments further includes an insulating layer formed on the substrate, in which the insulating layer includes at least one of a silicon oxide layer, a silicon nitride layer and a silicon oxynitride layer.

Referring to FIG. 2D, the gate stack structure 202 further includes an insulating layer 208 on the substrate 201. In the embodiments of the disclosure, the insulating layer may be a silicon oxide layer.

In some embodiments, the method further includes S206 of forming a sidewall structure on either side of the gate stack structure, in which the sidewall structure includes a nitride layer. Here, S206 may be performed after S204.

Based on S206, in some embodiments, the semiconductor structure further includes a sidewall structure on either side of the gate stack structure, in which the sidewall structure includes a nitride layer.

Referring to FIG. 2E, the semiconductor structure further includes a sidewall structure 209 located on either side of the gate stack structure 202. In the embodiments of the disclosure, the sidewall structure 209 may include a silicon nitride (Si₃N₄) layer.

In some embodiments, the thickness of the high-K dielectric layer is 20 to 40 angstroms (Å). Thus, the threshold voltage of the device can be effectively controlled, and the actual physical thickness can be increased as much as possible on the basis of ensuring the equivalent electrical thickness, so as to reduce the leakage current of the device and thus make the device more stable.

In some embodiments, the thickness of the first barrier layer is 2 to 10 Å. Thus, the influence of a too thick barrier layer on the adjustment of metal work function can be reduced, and the problem that the barrier layer is too thin to provide the effect of preventing oxygen from diffusing to the bottom also can be solved.

In some embodiments, the thickness of the gate electrode layer is 2 to 10 Å. Thus, the influence of the gate electrode thickness on the difference of metal-semiconductor contact work functions of the device can be reduced, and the connection resistance of the device can be reduced, thereby improving the device performance.

In some embodiments, the gate electrode layer includes a TiN layer. In other embodiments, the gate electrode layer may further include a TaN layer.

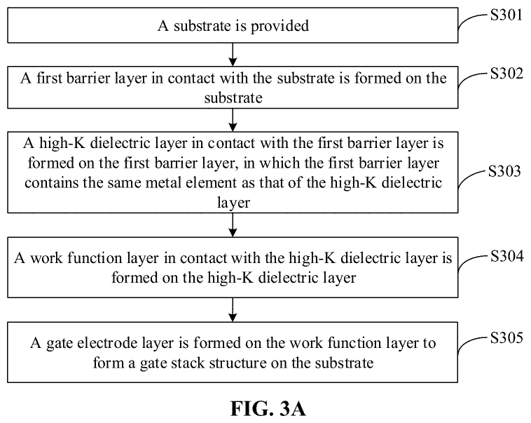

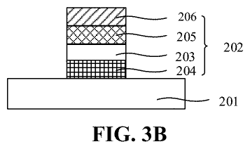

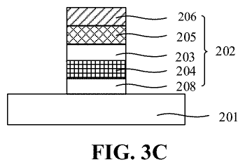

The embodiments of the disclosure provide a method for forming a semiconductor structure for the above-mentioned Case 2. Referring to FIG. 3A, the method includes S301 to S305.

At S301, a substrate is provided.

At S302, a first barrier layer in contact with the substrate is formed on the substrate.

At S303, a high-K dielectric layer in contact with the first barrier layer is formed on the first barrier layer, in which the first barrier layer contains the same metal element as that of the high-K dielectric layer.

At S304, a work function layer in contact with the high-K dielectric layer is formed on the high-K dielectric layer.

At S305, a gate electrode layer is formed on the work function layer, to form a gate stack structure on the substrate.

The S301 to S305 are further explained below with reference to FIG. 3B. Referring to FIG. 3B, a first barrier layer 204 in contact with the substrate 201 is formed on the substrate 201. A high-K dielectric layer 203 in contact with the first barrier layer 204 is formed on the first barrier layer 204. A work function layer 205 in contact with the high-K dielectric layer 203 is formed on the high-K dielectric layer 203. A gate electrode layer 206 in contact with the work function layer 205 is formed on the work function layer 205.

The embodiments of the disclosure provide a semiconductor structure for the above-mentioned Case 2, in which the first barrier layer may be in contact with the lower surface of the high-K dielectric layer. The semiconductor structure includes a substrate and a gate stack structure located on the substrate. The gate stack structure includes a high-k dielectric layer, a first barrier layer in contact with the high-K dielectric layer, a work function layer located on the side of the high-K dielectric layer away from the substrate, a gate electrode layer located on the side of the work function layer away from the substrate. The first barrier layer contains the same metal element as that of the high-K dielectric layer, and the first barrier layer is located on the side of the high-K dielectric layer close to the substrate.

The semiconductor structure provided in the embodiment is further described in detail below with reference to FIG. 3B.

Referring to FIG. 3B, the semiconductor structure includes a substrate 201 and a gate stack structure 202 on the substrate 201. The gate stack structure 202 includes a first barrier lay 204 in contact with that substrate 201, a high-K dielectric layer 203 in contact with the upper surface of the first barrier layer 204, a work function layer 205 located on the upper surface of the high-K dielectric layer 203, and a gate electrode layer 206 on the work function layer 205. In the embodiments of the disclosure, the substrate 201 is a silicon substrate, the high-K dielectric layer 203 is an HfSiON layer, the first barrier layer 204 is a LaHfOₓ layer, the work function layer 205 is a La₂O₃ layer, and the gate electrode layer 206 is a TaN layer. The first barrier layer 204 contains the same Hf element as that of the high-K dielectric layer 203.

In the embodiments of the disclosure, by providing the first barrier layer between the high-K dielectric layer and the substrate, the transmission of O to the substrate can be blocked, preventing the high-K dielectric layer from reacting with the substrate to generate oxygen vacancies and silicon dioxide, thereby reducing the drift of threshold voltage and improving the stability of the device. Moreover, the growth of the insulating layer can be reduced.

In some embodiments, the gate stack structure further includes an insulating layer formed on the substrate, in which the insulating layer includes at least one of a silicon oxide layer, a silicon nitride layer and a silicon oxynitride layer. Referring to FIG. 3C, the gate stack structure 202 further includes an insulating layer 208 formed on the substrate 201, in which the upper surface of the insulating layer 208 is in contact with the first barrier layer 204. In the embodiments of the disclosure, the insulating layer 208 is a silicon oxide layer.

In some embodiments, the thickness of the insulating layer is 10 to 40 Å.

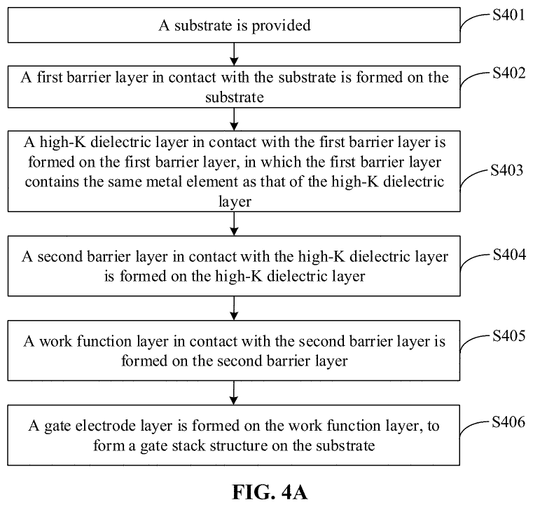

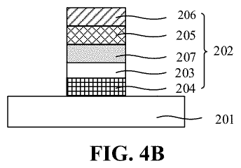

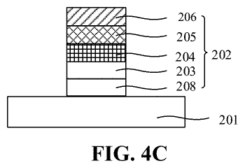

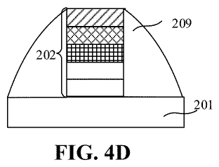

The embodiments of the disclosure provide a method for forming a semiconductor structure according to the above-mentioned Case 3. Referring to FIG. 4A, the method includes S401 to S406.

At S401, a substrate is provided.

At S402, a first barrier layer in contact with the substrate is formed on the substrate.

At S403, a high-K dielectric layer in contact with the first barrier layer is formed on the first barrier layer, in which the first barrier layer contains the same metal element as that of the high-K dielectric layer.

At S404, a second barrier layer in contact with the high-K dielectric layer is formed on the high-K dielectric layer.

At S405, a work function layer in contact with the second barrier layer is formed on the second barrier layer.

At S406, a gate electrode layer is formed on the work function layer, to form a gate stack structure on the substrate.

The S401 to S406 are further explained below with reference to FIG. 4B. S401 and S402 are performed to form on the substrate 201 the first barrier layer 204 in contact with the substrate 201. S403 is performed to form the high-K dielectric layer 203 contacting with the first barrier layer 204 on the first barrier layer 204. S404 is performed to form the second barrier layer 207 in contact with the high-K dielectric layer 203 on the high-K dielectric layer 203. S405 is performed to form the work function layer 205 in contact with the second barrier layer 207 on the second barrier layer 207. S406 is performed to form the gate electrode layer 206 on the work function layer 205 to form the gate stack structure 202 on the substrate 201.

Based on the method for forming a semiconductor structure provided in S401 to S406, the embodiments of the disclosure provide a semiconductor structure for above-mentioned Case 3, in which the first barrier layers are in contact with both the upper surface and the lower surface of the high-K dielectric layer. The semiconductor structure includes a substrate and a gate stack structure located on the substrate. The gate stack structure includes a high-K dielectric layer, a first barrier layer in contact with the high-K dielectric layer, a second barrier layer located on the side of the high-K dielectric layer away from the substrate and in contact with the high-K dielectric layer, a work function layer located on the side of the high-K dielectric layer away from the substrate, and a gate electrode layer located on the side of the work function layer away from the substrate. The first barrier layer contains the same metal element as that of the high-K dielectric layer, and the first barrier layer is located on the side of the high-K dielectric layer close to the substrate.

Referring to FIG. 4B, the semiconductor structure includes a substrate 201 and a gate stack structure 202 on the substrate 201. The gate stack structure 202 includes a first barrier layer 204 in contact with the substrate 201, a high-K dielectric layer 203 in contact with the upper surface of the first barrier layer 204, a second barrier layer 207 located on the upper surface of the high-K dielectric layer 203, a work function layer 205 located on the second barrier layer 207 (that is, the work function layer 205 is in contact with the upper surface of the second barrier layer 207), and a gate electrode layer 206 on the work function layer 205.

In the embodiments of the disclosure, by providing the first barrier layer and the second barrier layer in contact with the high-K dielectric layer, not only can the transmission of O in the high-K dielectric layer to the substrate be blocked, reducing the transmission of O, but also the oxygen in the air or the oxygen brought by the subsequent manufacturing process can be blocked from entering the gate electrode layer, the work function layer and the high-K dielectric layer, which is more conducive to prevent the high-K dielectric layer from reacting with the substrate to generate oxygen vacancies and silicon dioxide. Therefore, the drift of threshold voltage is further reduced and the stability of the device is further improved. Moreover, the growth of the insulating layer can be further reduced.

In some embodiments, the second barrier layer may be the same as the first barrier layer. For example, the first barrier layer includes a lanthanum hafnium oxide layer, and the second barrier layer includes a lanthanum hafnium oxide layer. In other embodiments, the second barrier layer may be different from the first barrier layer. This is not limited in the embodiments of the disclosure.

In some embodiments, the thickness of the second barrier layer may be the same as or different from the thickness of the first barrier layer.

The embodiments of the disclosure provide a semiconductor structure including a substrate and a gate stack structure located on the substrate. The gate stack structure includes an insulating layer formed on the substrate, a high-K dielectric layer, a first barrier layer in contact with the high-K dielectric layer, a work function layer located on the side of the high-K dielectric layer away from the substrate, and a gate electrode layer located on the side of the work function layer away from the substrate. The first barrier layer contains the same metal element as that of the high-K dielectric layer. The insulating layer includes at least one of a silicon oxide layer, a silicon nitride layer and a silicon oxynitride layer.

In the embodiments of the disclosure, the gate stack structure includes an insulating layer formed on the substrate, a high-K dielectric layer, a first barrier layer in contact with the high-K dielectric layer, a work function layer located on the side of the high-K dielectric layer away from the substrate, and a gate electrode layer located on the side of the work function layer away from the substrate. On the one hand, the laminated structure consisting of the insulating layer and the subsequently formed high-K gate dielectric layer is used as the gate dielectric layer. On the other hand, the insulating layer provides a good interface foundation for the subsequent formation of the high-K gate dielectric layer, thereby improving the quality of the formed high-K gate dielectric layer, reducing the interface-state density between the high-K gate dielectric layer and the substrate, and avoiding the adverse effects caused by the direct contact between the high-K gate dielectric layer and the substrate.

The semiconductor structure provided in the embodiments is further described in detail below with reference to FIG. 4C.

The semiconductor structure includes a substrate 201 and a gate stack structure 202 on the substrate 201. The gate stack structure 202 includes an insulating layer 208 (maybe a silicon oxynitride layer) formed on the substrate, a high-K dielectric layer 203 on the insulating layer 208, a first barrier layer 204 in contact with the high-K dielectric layer 203, a work function layer 205 on the high-K dielectric layer 203, and a gate electrode layer 206 on the work function layer 205. In the embodiments of the disclosure, the substrate 201 is a silicon substrate, the high-K dielectric layer 203 is an HMO layer, the first barrier layer 204 is a LaHfOₓ layer, the work function layer 205 is a La₂O₃ layer, and the gate electrode layer 206 is a TaN layer. The first barrier layer 204 contains the same Hf element as that of the high-K dielectric layer 203.

In some embodiments, the semiconductor structure further includes a sidewall structure located on either side of the gate stack structure, in which the sidewall structure includes a nitride layer. Referring to FIG. 4D, the semiconductor structure further includes the sidewall structures 209 located on both sides of the gate stack structure 202. In the embodiments of the disclosure, the sidewall structure 209 may be a SiO₂—Si₃N₄—SiO₂ (ONO) multilayer structure.

In some embodiments, the semiconductor structure further includes a LDD structure and a halo ring. Halo ions are used to implant in the LDD structure to increase the doping concentrations at the interfaces between the substrate and the source and the drain, thereby reducing the widths of the source and drain depletion regions to suppress the drain-induced barrier reduction effect in short-channel devices.

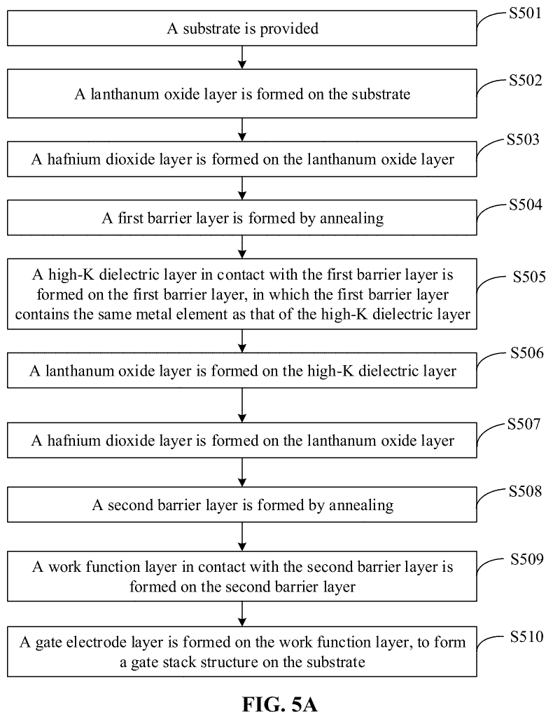

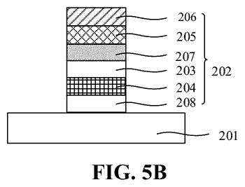

The embodiments of the disclosure provide a method for forming a semiconductor structure. As shown in FIG. 5A, the first barrier layer includes a lanthanum hafnium oxide layer, and the second barrier layer includes a lanthanum hafnium oxide layer. The method includes S501 to S510.

At S501, a substrate is provided.

At S502, a lanthanum oxide layer is formed on the substrate.

The lanthanum oxide layer may be formed by Molecular Beam Epitaxy (MBE), ALD, CVD, etc. In some embodiments, the thickness of the La₂O₃ layer may be 2 to 10 Å.

At S503, a hafnium dioxide layer is formed on the lanthanum oxide layer.

Hafnium dioxide may be formed by ALD, CVD, MBE, etc.

At S504, a first barrier layer is formed by annealing.

The annealing may be rapid thermal annealing, flash annealing, peak annealing, laser annealing, etc. The annealing atmosphere may contain O₂ and one or more of N₂, Ar or He. The annealing temperature may be 300 to 1000 degrees Celsius (° C.), and the first barrier layer formed includes a LaHfOₓ layer. In the annealed first barrier layer, the density of oxygen vacancies decreases. Moreover, the formation energy of oxygen vacancies near La is higher, so that it is difficult for external oxygen to be transmitted to the dielectric layer with high-density oxygen vacancies through the dielectric layer with low-density oxygen vacancies, reducing or even eliminating the interference of external oxygen on the device, and thus achieving the purpose of improving the stability of the device. Moreover, the first barrier layer is formed by annealing, so that the first barrier layer contains the same metal element as that of the high-K dielectric layer, which can effectively reduce the manufacturing process flow and improve the efficiency.

At S505, a high-K dielectric layer in contact with the first barrier layer is formed on the first barrier layer, in which the first barrier layer contains the same metal element as that of the high-K dielectric layer.

At S506, a lanthanum oxide layer is formed on the high-K dielectric layer.

At S507, a hafnium dioxide layer is formed on the La₂O₃ layer.

At S508, a second barrier layer is formed by annealing.

The S506 to S508 can be implemented with reference to the S502 to S504.

At S509, a work function layer in contact with the second barrier layer is formed on the second barrier layer.

At S510, a gate electrode layer is formed on the work function layer, to form a gate stack structure on the substrate.

In the embodiments of the disclosure, a lanthanum oxide layer is formed on the substrate or the high-K dielectric layer, a hafnium dioxide layer is formed on the lanthanum oxide layer, and a lanthanum hafnium oxide layer is formed by annealing. In the annealed first barrier layer, the density of oxygen vacancies decreases. Moreover, the energy needed to form oxygen vacancies near La is higher, so that it is difficult for external oxygen to be transmitted to the dielectric layer with high-density oxygen vacancies through the dielectric layer with low-density oxygen vacancies, reducing or even eliminating the interference of external oxygen on the device, and thus achieving the purpose of improving the stability of the device. Moreover, the first barrier layer is formed by annealing, so that the first barrier layer contains the same metal elements as that of the high-K dielectric layer, which can effectively reduce the manufacturing process flow and improve the efficiency.

In some embodiments, the gate electrode layer includes a TiN layer or a TaN layer.

In some embodiments, the thickness of the high-K dielectric layer is 20 to 40 Å.

In some embodiments, the thickness of the first barrier layer is 2 to 10 Å.

In some embodiments, the thickness of the gate electrode layer is 2 to 10 Å.

In some embodiments, the method further includes S511 of forming an insulating layer on the substrate, in which the insulating layer includes at least one of a silicon oxide layer, a silicon nitride layer and a silicon oxynitride layer. Here, S511 is executed after S501. The S511 and the S502 to S511 can be performed with reference to FIG. 5B. An insulating layer 208 is formed on the substrate 201. A lanthanum oxide layer and a hafnium dioxide layer are formed sequentially on the insulating layer 208, and the first barrier layer 204 is formed by annealing. A high-K dielectric layer 203 is formed on the first barrier layer 204, and a lanthanum oxide layer is formed on the high-K dielectric layer 203. A hafnium dioxide layer is formed on the lanthanum oxide layer, and a second barrier layer 207 is formed by annealing. A work function layer 205 is formed on the second barrier layer 207. A gate electrode layer 206 is formed on the work function layer 205, to form a gate stack structure 202 on the substrate 201. Therefore, the gate stack structure 202 includes the insulating layer 208, the first barrier layer 204, the high-K dielectric layer 203, the second barrier layer 207, the work function layer 205 and the gate electrode layer 206.

In some embodiments, the thickness of the insulating layer is 10 to 40 Å.

The features disclosed in the method embodiments or the semiconductor structure embodiments provided by the disclosure can be arbitrarily combined, under the condition of no conflict, to obtain new method embodiments or semiconductor structure embodiments.

The above description of the semiconductor structure embodiments is similar to the above description of the method embodiments, and has the similar beneficial effects as the method embodiments. For the technical details not disclosed in the semiconductor embodiments of the disclosure, please refer to the description of the method embodiments of the disclosure for understanding.

What has been described above is only exemplary embodiments of the disclosure, and is not intended to limit the scope of protection of the disclosure. Any modification, equivalent replacement and improvement within the spirit and principle of the disclosure shall be included in the scope of protection of the disclosure.

What is claimed is:

1. A semiconductor structure, comprising: a substrate and a gate stack structure located on the substrate; wherein the gate stack structure comprises:
a high-K dielectric layer;
a first barrier layer in contact with the high-K dielectric layer;
a work function layer located on a side of the high-K dielectric layer away from the substrate; and
a gate electrode layer located on a side of the work function layer away from the substrate;
wherein the first barrier layer contains a same metal element as the high-K dielectric layer.

2. The structure according to claim 1, wherein the first barrier layer is located on a side of the high-K dielectric layer close to the substrate.

3. The structure according to claim 2, further comprising: a second barrier layer located on the side of the high-K dielectric layer away from the substrate and in contact with the high-K dielectric layer.

4. The structure according to claim 1, wherein the first barrier layer is located on the side of the high-K dielectric layer away from the substrate.

5. The structure according to claim 3, wherein the first barrier layer comprises a lanthanum hafnium oxide layer, and the second barrier layer comprises a lanthanum hafnium oxide layer.

6. The structure according to claim 1, wherein the high-K dielectric layer comprises at least one of a hafnium silicon oxide layer, a hafnium silicon oxynitride layer, a hafnium tantalum oxide layer, a hafnium titanium oxide layer or a hafnium zirconium oxide layer.

7. The structure according to claim 1, wherein the gate electrode layer comprises a titanium nitride layer.

8. The structure according to claim 1, wherein the gate stack structure further comprises an insulating layer formed on the substrate, wherein the insulating layer comprises at least one of a silicon oxide layer, a silicon nitride layer or a silicon oxynitride layer, and a thickness of the insulating layer is 10 to 40 Å.

9. The structure according to claim 1, further comprising:
a sidewall structure located on either side of the gate stack structure, wherein the sidewall structure comprises a nitride layer.

10. The structure according to claim 1, wherein a thickness of the high-K dielectric layer is 20 to 40 Å, a thickness of the first barrier layer is 2 to 10 Å, and a thickness of the gate electrode layer is 2 to 10 Å.

11. A method for forming a semiconductor structure, comprising:
providing a substrate;
forming a high-K dielectric layer and a first barrier layer in contact with the high-K dielectric layer on the substrate;
forming a work function layer on a side of the high-K dielectric layer away from the substrate; and
forming a gate electrode layer on the work function layer, such that a gate stack structure is formed on the substrate,
wherein the first barrier layer contains a same metal element as the high-K dielectric layer.

12. The method according to claim 11, wherein the forming the high-K dielectric layer and the first barrier layer in contact with the high-K dielectric layer on the substrate comprises:
forming the first barrier layer in contact with the substrate on the substrate;
forming the high-K dielectric layer in contact with the first barrier layer on the first barrier layer; and
the forming the work function layer on the side of the high-K dielectric layer away from the substrate comprises:
forming the work function layer in contact with the high-K dielectric layer on the high-K dielectric layer.

13. The method according to claim 11, further comprising:
forming a second barrier layer in contact with the high-K dielectric layer on the high-K dielectric layer;
wherein the forming the high-K dielectric layer and the first barrier layer in contact with the high-K dielectric layer on the substrate comprises:
forming the first barrier layer in contact with the substrate on the substrate;
forming the high-K dielectric layer in contact with the first barrier layer on the first barrier layer; and
the forming the work function layer on the side of the high-K dielectric layer away from the substrate comprises:
forming the work function layer in contact with the second barrier layer on the second barrier layer.

14. The method according to claim 11, wherein the forming the high-K dielectric layer and the first barrier layer in contact with the high-K dielectric layer on the substrate comprises:
forming the high-K dielectric layer in contact with the substrate on the substrate;
forming the first barrier layer in contact with the high-K dielectric layer on the high-K dielectric layer; and
the forming the work function layer on the side of the high-K dielectric layer away from the substrate comprises:
forming the work function layer in contact with the first barrier layer on the first barrier layer.

15. The method according to claim 13, wherein the first barrier layer comprises a lanthanum hafnium oxide layer, and the second barrier layer comprises a lanthanum hafnium oxide layer, wherein a method for forming the lanthanum hafnium oxide layer comprises:
forming a lanthanum oxide layer on the substrate or the high-K dielectric layer;
forming a hafnium dioxide layer on the lanthanum oxide layer; and
forming the lanthanum hafnium oxide layer by annealing.

16. The method according to claim 11, wherein the high-K dielectric layer comprises at least one of a hafnium silicon oxide layer, a hafnium silicon oxynitride layer, a hafnium tantalum oxide layer, a hafnium titanium oxide layer or a hafnium zirconium oxide layer.

17. The method according to claim 11, wherein the gate electrode layer comprises a titanium nitride layer.

18. The method according to claim 11, wherein a thickness of the high-K dielectric layer is 20 to 40 Å, a thickness of the first barrier layer is 2 to 10 Å, and a thickness of the gate electrode layer is 2 to 10 Å.

19. The method according to claim 11, further comprising:
forming an insulating layer on the substrate, wherein the insulating layer comprises at least one of a silicon oxide layer, a silicon nitride layer or a silicon oxynitride layer, and a thickness of the insulating layer is 10 to 40 Å.

20. The method according to claim 11, further comprising: forming a sidewall structure on either side of the gate stack structure, wherein the sidewall structure comprises a nitride layer.
